(19) United States
(12) Patent Application Publication
(10) Pub. No.: US 2026/0362055 A1
(43) Pub. Date: Nov. 12, 2026

(54) Method for Operating an Audio System for a Vehicle, and Audio System

(71) Applicant: Mercedes-Benz Group AG, Stuttgart (DE)

(72) Inventor: Thomas KUEPPERS, Altdorf (DE)

(21) Appl. No.: 19/131,350

(22) PCT Filed: Nov. 17, 2023
(86) PCT No.: PCT/EP2023/082264

§ 371 Date: May 20, 2025

(30) Foreign Application Priority Data
Nov. 21, 2022 (DE) 10 2022 004 346.7

(51) Int. Cl. H04R 3/12; H03F 3/183; H04R 5/02; H04S 3/00

(52) U.S. Cl. CPC H04R 3/12; H04R 5/02; H04S 3/008; H03F 3/183; H03F 2200/03; H04R 2499/13; H04S 2400/01; H04S 2400/13

(57) ABSTRACT

A method for operating an audio system having a plurality of audio sources and a plurality of loudspeaker channels for a plurality of loudspeakers of a vehicle. The method includes, via a logic-based controller, monitoring activity states of the plurality of audio sources and deactivating at least one of the plurality of loudspeaker channels when all audio sources assigned to the at least one of the plurality of loudspeaker channels are inactive.

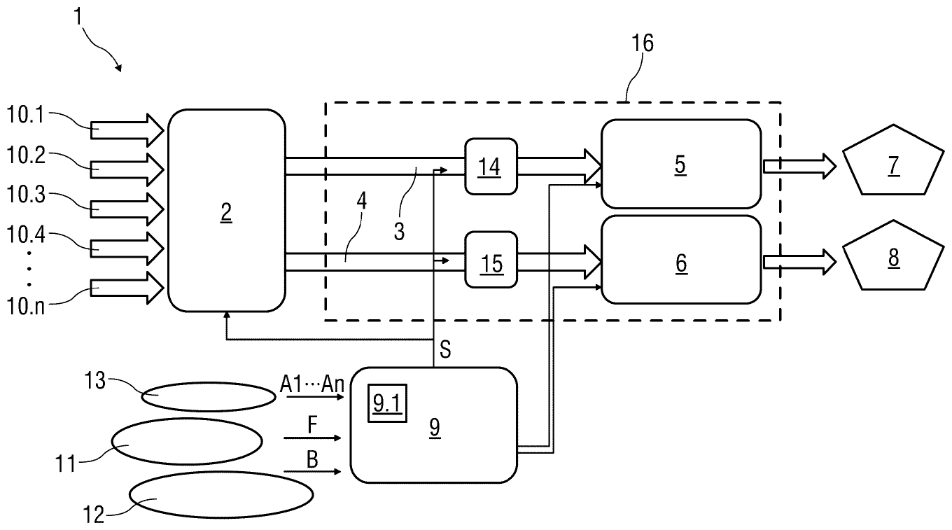

### BACKGROUND AND SUMMARY OF THE INVENTION

The invention relates to a method for operating an audio system for a vehicle. The invention furthermore relates to an audio system for a vehicle.

A control device for an audio amplifier for reducing disruptive influences on audio signals to be played back is known from DE 198 15 923 A1. The control device reduces the power of the audio amplifier when disruptive influences on audio signals to be played back occur, in order to reduce the playback volume of the audio signals. Once the disruptive influences on the audio signals to be played back have ceased, the control device increases the power of the audio amplifier to the value set before the reduction.

Furthermore, a method and a device for dynamic management of a dead time between switching on output power stage transistors in audio amplifiers are known from US 2017/0250654 A1. In the method, a drive signal based on an input signal is created, wherein the drive signal is amplified by alternating control of a first transistor and a second transistor with time between the deactivation of the first transistor and the activation of the second transistor. The time is adjusted during amplification based on a parameter of the input signal or the drive signal. The parameter is an amplitude of the input signal, a duty cycle of the drive signal or a duty cycle of a pulse-width modulated signal, which is created based on the input signal. The input signal is a digital audio input signal.

An audio system is known from DE 10 2021 003 593 A1, which is deactivated to save energy when there is no audio signal or when there is a mute command. An audio system is known from US 2019/0007777 A1, which switches between two modes depending on seat occupancy of seats.

The invention is based on the object of specifying a novel method for operating an audio system for a vehicle and a novel audio system for a vehicle.

According to the invention, in the method for operating an audio system for a vehicle, activity states of audio sources are monitored by means of a logic-based controller and at least one loudspeaker channel of a digital audio power amplifier is deactivated when all audio sources assigned to this loudspeaker channel are inactive.

In present-day audio entertainment systems in vehicles, in addition to acoustic output of classical entertainment content, such as radio content, for example, there is also an acoustic output of a sound design and audio signals assigned to different vehicle functions, for example the sounds of a turn indicator, warning sounds, parking assist sounds etc. Due to the large number of loudspeakers installed in or on the vehicle, audio amplifiers of the audio entertainment systems consume energy even if not all loudspeaker channels are required. This results from the fact that, for example, audio signals are created by using a so-called audio programming platform on the audio power amplifier itself and passed on to another amplifier system or the loudspeakers for playback, in which case conversion modules used here, i.e., in particular a digital-to-analog converter and the audio power amplifier, cause power losses even when the audio output is not used, i.e., when the signal content is zero. While a complete shut-down of the audio power amplifier, inclusive of its power supply, offers great energy-saving potential, this however only enables deactivation of all loudspeaker channels.

In contrast, the present method enables loudspeaker channels to be turned on and off very dynamically during the runtime by complex logic scenarios using current system states in the vehicle, in order to realize energy savings in the case of loudspeaker channels that are not needed. Activation and deactivation of a loudspeaker channel takes some time, however, and thus disturbs responsiveness when playing back audio signals, which can lead to audible audio artefacts. The present method enables predictive deactivation and activation of the loudspeaker channels because, in particular in addition to taking into account signal content of an audio signal to be output, the activity of the audio sources is taken into account, so that audible audio artefacts and the “swallowing” of sounds can be effectively avoided during activation. Thus, a function of the audio system is unaffected from a user's perspective. Consequently, energy consumption in the real vehicle operation can be reduced without restrictions for a vehicle user. In particular, the method can be realized by means of flexibly adaptable software. This means that the security for eliminating audio artefacts is increased, as a software component can be programmed by a vehicle manufacturer within sound functions. This also means that deactivation of the loudspeaker channels can be handled differently in a simple manner between different vehicle series or different audio systems.

In one possible embodiment of the method, audio signals of active audio sources are multiplexed onto at least one loudspeaker channel. Due to this multiplexing, audio signals processed on infrequently used loudspeaker channels can be transmitted to other loudspeaker channels, for example, so that the infrequently used loudspeaker channels can be deactivated.

In a further possible embodiment of the method, a driving state of the vehicle and/or operating parameters of the vehicle and/or operating parameters of vehicle systems are or is taken into account when monitoring the activity states of the audio sources. This enables an assessment of which audio signals or audio content has to be played, so that, particularly advantageously, only those loudspeaker channels whose use is considered particularly improbable in a currently determined situation are deactivated. For example, the outputting of signal sounds from a parking assist is not required when the vehicle is being driven at vehicle speeds of more than 30 km/h, meaning that loudspeaker channels that output these signal sounds can be deactivated when other audio sources using these loudspeaker channels are inactive.

In a further possible embodiment of the method, when a loudspeaker channel is deactivated, initially the loudspeaker channel is muted and then an amplifier module located in the loudspeaker channel is deactivated. This enables audible disruptive noises, for example a cracking or crackling, to be avoided when deactivating the corresponding loudspeaker channel.

In a further possible embodiment of the method, audio signals output in an activated state by means of coupled audio sources are amplified by means of amplifier modules located in the loudspeaker channels. This enables separate amplification of the audio signals for each loudspeaker channel.

In a further possible embodiment of the method, for each activated loudspeaker channel, a received digital audio signal is converted into an analog audio signal by means of pulse-width modulation before being forwarded to the corresponding loudspeaker. This enables the processing of digital audio signals and the output of analog audio signals.

In a further possible embodiment of the method, the muting of a loudspeaker channel is carried out by means of deactivating the pulse-width modulation. This represents a simple and reliable deactivation.

An audio system for a vehicle comprises several audio sources and at least one digital audio power amplifier coupled to the audio sources and having several loudspeaker channels. In this case, the loudspeaker channels each amplify audio signals output by means of at least one audio source and transmit the amplified audio signals to at least one coupled loudspeaker.

According to the invention, at least one control unit with a logic-base controller is provided, wherein the control unit is designed to monitor activity states of audio sources and to deactivate at least one loudspeaker channel when all audio sources assigned to this loudspeaker channel are inactive.

The audio system enables loudspeaker channels to be turned on and off very dynamically during the runtime by complex logic scenarios using current system states in the vehicle, in order to realize energy savings in the case of loudspeaker channels that are not needed. Activation and deactivation of a loudspeaker channel takes some time, however, and thus disturbs responsiveness when playing back audio signals, which can lead to audible audio artefacts. The audio system, however, enables predictive deactivation and activation of the loudspeaker channels because, in particular in addition to taking into account signal content of an audio signal to be output, the activity of the audio sources is taken into account, so that audible audio artefacts and the “swallowing” of sounds can be effectively avoided during activation. Thus, a function of the audio system is unaffected from a user's perspective. Consequently, energy consumption in the real vehicle operation can be reduced without restrictions for a vehicle user. In particular, a deactivation function of the loudspeaker channels can be realized by means of flexibly adaptable software. This means that the security for eliminating audio artefacts is increased, as a software component can be programmed by a vehicle manufacturer within sound functions. This also means that deactivation of the loudspeaker channels can be handled differently in a simple manner between different vehicle series or different audio systems.

In one possible embodiment of the audio system, the control unit is furthermore designed to multiplex audio signals of active audio sources onto at least one loudspeaker channel. Due to this multiplexing, processed audio signals processing on infrequently used loudspeaker channels can be transmitted to other loudspeaker channels, for example, meaning that the infrequently used loudspeaker channels can be deactivated.

Exemplary embodiments of the invention are explained in more detail in the following using the drawing.

### BRIEF DESCRIPTION OF THE DRAWING

The FIGURE schematically shows a block diagram of an audio system for a vehicle.

### DETAILED DESCRIPTION OF THE DRAWING

In the FIGURE, a block diagram of an audio system 1 for a vehicle is illustrated.

The audio system 1 comprises a distribution module 2, two loudspeaker channels 3, 4, a digital audio power amplifier 16 having two amplifier modules 5, 6, two loudspeakers 7, 8, a control unit 9 and several audio sources 10.1 to 10.n. Furthermore, the audio system comprises a data source 11 for driving state parameters F of the vehicle, a data source 12 for particular operating parameters B of the vehicle and/or of vehicle systems and a data source 13 for transmitting activity states A1 to An of the audio sources 10.1 to 10.n to the control unit 9. In each case, a mute switching device 14, 15 is arranged in the loudspeaker channels 3, 4.

In the audio system 1, audio processing software implemented in the distribution module 2 distributes audio content that is output and to be played by the audio sources 10.1 to 10.n to the different loudspeaker channels 3, 4 present in the vehicle. In embodiments not shown in detail, in a deviation from the two loudspeaker channels 3, 4 shown to illustrate the audio system 1, any other plurality of loudspeaker channels 3, 4 and loudspeakers 7, 8 is possible. The audio content is converted into electrical signals and amplified, so that the loudspeakers 7, 8 can emit a corresponding sound. This amplification takes place in the amplifier modules 5, 6, wherein these themselves create a power loss when there is no audio signal present for amplification. However, they do not create any power loss when the amplifier modules 5, 6 are in the deactivated state.

Activating and deactivating the amplifier module 5, 6 can be realized in different ways and enables different energy-saving potentials depending on the method used. In this case, either the entire audio power amplifier 16 can be activated or deactivated or, as is possible in a digital audio power amplifier 16, pulse-width modulation is activated or deactivated, by means of which a digital audio signal output by the audio sources 10.1 to 10.n is converted into an analog audio signal before being forwarded to the corresponding loudspeaker 7, 8. While activation and deactivation of the entire audio power amplifier 16 usually affects several loudspeaker channels 3, 4, activation and deactivation of the pulse-width modulation enables separate activation and deactivation for each loudspeaker channel 3, 4 in digital audio power amplifiers 16.

Both methods, however, require a certain amount of time for a chip of the audio power amplifier 16 to be uploaded or downloaded. Playback of the audio content is not possible during this time frame. A reaction time of, for example, 50 ms to 500 ms of the audio power amplifier 16 or the amplifier modules 5, 6 for the uploading is so long so that a resulting dead time can be perceived as disruptive by a vehicle user. If the loudspeakers 7, 8 are also used to output notification and/or alert sounds, shorter reaction times are prescribed by law. Therefore, deactivation of the audio power amplifier 16 or the amplifier module 5, 6 depending merely on an analysis of whether audio data is present or not for a loudspeaker channel 7, 8 is not effective as a control variable for activation and deactivation.

In order to minimize the power loss and thus energy consumption of the audio system 1 and consequently of the vehicle, it is provided that at least one loudspeaker channel 3, 4 of the digital audio power amplifier 16 is deactivated by means of logic-based controller 9.1 implemented in the control unit 9 when all audio sources 10.1 to 10.n assigned to this loudspeaker channel 3, 4 are inactive. Therefore, monitoring the activity states A1 to An of the audio sources 10.1 to 10.n takes place by means of the control unit 9. Additionally, the driving state parameters F of the vehicle and operating parameters B of the vehicle and/or of vehicle systems can be taken into account when activating and deactivating the loudspeaker channels 3, 4.

The logic-based controller 9.1 is implemented, for example, as software module in the control unit 9 and comprises, for example, so-called communication middleware for Ethernet communication in the vehicle and, for example, is designed for serialization and for exchange of information. The logic-based controller 9.1 selects which loudspeaker channel 3, 5 can be activated or deactivated, depending on different input parameters. For example, using activity states A1 to An, it is checked whether in general a radio function is active, or a permanent sound synthesis is active. Using the driving state parameters F, it is checked, for example, how great a vehicle speed of the vehicle is, according to which it can be assessed which information sound or warning sound has to be played by means of the loudspeakers 7, 8. For example, it can be specified that a vehicle warning sound generator (acoustic vehicle alert system; abbr. AVAS) is not active when vehicle speeds are greater than 30 km/h, and/or that all loudspeakers 7, 8 in the vehicle interior have to be active when vehicle speeds are below 20 km/h, because sounds are to be output from a parking assist, for example. Using the operating parameters B of the vehicle and/or of vehicle systems, it can be checked whether a special energy-saving mode has been activated.

Depending on the activity states A1 to An and if necessary the driving state parameters F and the operating parameters B, the control unit 9 forms an output signal S, by means of which the corresponding loudspeaker channel 3, 4 is initially muted by means of the mute switching devices 14, 15 in the case of deactivation and only then is the respective amplifier module 5, 6 deactivated. This can prevent audible disruptive noises, in particular crackling, which can be caused by deactivating the respective amplifier module 5, 6.

In addition, the output signal S can also be used to influence the audio processing software implemented in the distribution module 2, so that the software is instructed, for example, not to integrate certain loudspeaker channels 3, 4 into the audio playback or to set an emergency channel mix. This means that disruptive effects experienced by the user during switching or in the event of a fault can be avoided.

The separate control of individual loudspeaker channels 3, 4 can ensure that loudspeaker channels 3, 4 required for an operating state remain active and all other loudspeaker channels 3, 4 can be taken into account for an energy-saving state. Audio signals from active audio sources 10.1 to 10.n can also be multiplexed onto at least one loudspeaker channel 3, 4 so that other loudspeaker channels 3, 4 can be deactivated to save energy.

For example, the software module implemented in the in the control unit 9 to realize the logic-based controller can be integrated using freely programmable middleware. This allows a deactivation algorithm for the loudspeaker channels 3, 4 and associated parameters, such as deactivation speeds, to be flexibly adapted to a vehicle development process or transferred to vehicles via an over-the-air update. Simultaneously, harmonization of the extent of the deactivation option of the loudspeaker channels 3, 4 with audio sources 10.1 to 10.n contained in the vehicle, properties of these, the number of loudspeaker channels, types of audio power amplifiers 16 and increasing experience and/or development progress can be realized.

It is also possible for more than one software module to be used to deactivate the loudspeaker channels 3, 4. For example, a software module can be provided for controlling loudspeaker channels 3, 4 for loudspeakers 7, 8 arranged inside the vehicle and another software module for loudspeakers 7, 8 arranged outside the vehicle and intended to emit external sounds. As software for external sounds is subject to mandatory certification, software modules for external loudspeakers 7, 8 may no longer be modified beyond a certain point in time. By separating the software module for deactivating internal and external loudspeaker channels 3, 4 as described, the flexibility in the development process for the internal loudspeaker channels 3, 4 is maintained despite a so-called certification freeze of the external loudspeaker channels 3, 4.

The following table shows which loudspeakers 7, 8 or loudspeaker channels 3, 4 are used for certain audio sources 10.1 to 10.n in a vehicle, for example.

TABLE 1
Audio source

| | | |
|---|---|---|
| Entertainment | radio, CD, USB, Bluetooth | all loudspeaker channels |
| audio | | |
| Phone | telephone | infotainment loudspeaker |
| | | channels |
| ICC | In-Car Communication | almost all loudspeaker |
| | | channels |
| ESS/ESS-EV | driving sound for vehicles | all loudspeaker channels |
| | with an internal combustion | |
| | engine/driving sound for | |
| | vehicles with electric drive | |
| RNC/EOC | road noise cancellation | all loudspeaker channels |
| | and/or engine order | |
| | cancellation | |
| | (active anti-noise) | |
| Pre-Safe | sound impulse directly | fixed defined loudspeaker |
| Sound | before an accident | set |
| AVAS | pedestrian warning sound | outside loudspeaker in the |
| | outside for vehicles with | respective driving direction |
| | electric drive up to 30 km/h | |
| Touch click | operator feedback | front loudspeaker channels |
| | touchscreen | |
| Navigation | navigation | infotainment loudspeaker |
| system | announcements | channels |
| SDS | speech dialogue with voice | infotainment loudspeaker |
| | control | channels |
| BSM, collision | blind spot monitor, | front loudspeaker channels |
| warning, | collision warning, | |
| warnings | distance warning, | |
| | warning noises | |
| Parking | soundtrack for a distance | almost all loudspeaker |
| assist | warning when parking | channels |
| Seatbelt | seatbelt warning, if | almost all loudspeaker |
| warning | necessary, seat-based | channels |

1.-9. (canceled)

10. A method for operating an audio system (1) having a plurality of audio sources (10.1 to 10.n) and a plurality of loudspeaker channels (3, 4) for a plurality of loudspeakers (7, 8) of a vehicle, the method comprising the steps of:
via a logic-based controller (9.1):
monitoring activity states (A1 to An) of the plurality of audio sources (10.1 to 10.n); and
deactivating at least one of the plurality of loudspeaker channels (3, 4) when all audio sources assigned to the at least one of the plurality of loudspeaker channels (3, 4) are inactive.

11. The method according to claim 10, wherein audio signals of active audio sources are multiplexed onto at least one of the plurality of loudspeaker channels (3, 4).

12. The method according to claim 10, wherein:
driving state parameters (F) of the vehicle; and/or
operating parameters (B) of the vehicle; and/or
operating parameters (B) of vehicle systems;
are taken into account during the monitoring.

13. The method according to claim 10, wherein when a loudspeaker channel (3, 4) of the plurality of loudspeaker channels (3, 4) is deactivated, initially muting the deactivated loudspeaker channel (3, 4) and then deactivating an amplifier module (5, 6) located in the deactivated loudspeaker channel (3, 4).

14. The method according to claim 10, wherein audio signals output in an activated state via coupled audio sources (10.1 to 10.n) are amplified by amplifier modules (5, 6) located in the plurality of loudspeaker channels (3, 4).

15. The method according to claim 14, wherein for each activated loudspeaker channel (3, 4), a received digital audio signal is converted into an analog audio signal by pulse-width modulation before being forwarded to the corresponding loudspeaker (7, 8).

16. The method according to claim 13, wherein the muting is carried out by deactivating pulse-width modulation.

17. An audio system (1) of a vehicle, comprising:
a plurality of audio sources (10.1 to 10.n);
at least one digital audio power amplifier (16) coupled to the plurality of audio sources (10.1 to 10.n) and having a plurality of loudspeaker channels (3, 4) for a plurality of loudspeakers (7, 8), wherein the plurality of loudspeaker channels (3, 4) each amplify audio signals output by the plurality of audio sources (10.1 to 10.n) and transmit amplified audio signals to at least one coupled loudspeaker (7, 8) of the plurality of loudspeakers (7,8); and
a control unit (9) with a logic-based controller (9.1), wherein the control unit (9) is configured to:
monitor activity states (A1 to An) of the plurality of audio sources (10.1 to 10.n); and
deactivate at least one of the plurality of loudspeaker channels (3, 4) when all audio sources assigned to the at least one of the plurality of loudspeaker channels (3, 4) are inactive.

18. The audio system (1) according to claim 17, wherein the control unit (9) is configured to multiplex audio signals of active audio sources (10.1 to 10.n) onto at least one of the plurality of loudspeaker channel (3, 4).
